(19) United States
(12) Patent Application Publication
(10) Pub. No.: US 2024/0081129 A1
(43) Pub. Date: Mar. 7, 2024

(54) STRETCHABLE OPTICAL DEVICE AND METHOD FOR MANUFACTURING THEREOF

(71) Applicant: KOREA UNIVERSITY RESEARCH AND BUSINESS FOUNDATION, SEJONG CAMPUS, Sejong-si (KR)

(72) Inventors: Mun Pyo HONG, Seongnam-si (KR); Seung Min SHIN, Incheon (KR)

(73) Assignee: KOREA UNIVERSITY RESEARCH AND BUSINESS FOUNDATION, SEJONG CAMPUS, Sejong-si (KR)

(21) Appl. No.: 18/244,579

(22) Filed: Sep. 11, 2023

Related U.S. Application Data
(63) Continuation of application No. PCT/KR2022/003408, filed on Mar. 11, 2022.

(30) Foreign Application Priority Data
Mar. 11, 2021 (KR) 10-2021-0032035
Dec. 14, 2021 (KR) 10-2021-0178315

(51) Int. Cl. H10K 59/80; H10K 59/12

(52) U.S. Cl. CPC H10K 59/873; H10K 59/1201; H10K 2102/311

(57) ABSTRACT

A stretchable optical device comprises: a flexible substrate divided into M×N pixels; a first thin film sealing layer formed on the flexible substrate, located inside a pixel, and formed from a first inorganic material; an actuation device layer located inside the pixel and formed on the first thin film sealing layer; a light-emitting layer located inside the pixel and connected to the actuation device layer; a second thin film sealing layer located inside the pixel, formed on the light-emitting layer, coming into contact with the first thin film sealing layer, and formed from a second inorganic material; a third thin film sealing layer located inside the pixel, formed on the second thin film sealing layer, and formed from a composite material of an organic material and an inorganic material; and a flexible film adhered to the flexible substrate, the stretchable optical device divided into a high flexible area, which is dependent on the shape of the flexible film and has stretchable folds, and a low flexible area (pixel area) in which deformation of the flexible film is minimum.

### TECHNICAL FIELD

The present invention relates to a stretchable optical device and a method for manufacturing the same, and more specifically, to a stretchable optical device and a method for manufacturing the same to have excellent external air blocking properties and elongation properties.

### BACKGROUND ART

Recently, organic light emitting diodes are being applied to universal displays such as mobile phones, televisions and monitors. Since the organic light emitting diodes are very vulnerable to moisture and oxygen, thereby causing deterioration, an encapsulation is essentially applied to prevent the deterioration.

Sine the commonly used hard displays in the related art have organic light emitting diodes mounted thereon so as to be protected from external air through a material such as a glass substrate, long-term reliability of the display is ensured.

However, as the need for development of stretchable displays having broad development values are increased, studies have been conducted on materials for stretchable thin film encapsulation for the most recently produced flexible displays so as to be freely extended and shortened beyond bendable, rollable and foldable stages.

In general, the polymer organic material-based thin film encapsulation for allowing some degree of stretching deformation without cracks has very poor external air blocking properties, and accordingly, fails to ensure even short-term reliability for a display.

In addition, the inorganic-based thin film encapsulation technology has been developed to be applicable to the above-mentioned bendable, rollable and foldable stages, however, it is still insufficient to be applied to the stretchable stage.

### DISCLOSURE

### Technical Problem

One technical problem to be solved by the present invention is to provide a stretchable optical device and a method for manufacturing the same to have excellent external air blocking properties and elongation properties.

The technical problems to be solved by the present invention are not limited to the above description.

### Technical Solution

In order to solve the above technical problems, the present invention provides a stretchable optical device.

According to one embodiment, the stretchable optical device includes: a flexible substrate divided into M (a positive integer of 1 or more)×N (a positive integer of 1 or more) pixels; a first thin film encapsulation layer formed on the flexible substrate, located in the pixel, and formed of a first inorganic material; an actuation device layer located in the pixel and formed on the first thin film encapsulation layer; an emission layer located in the pixel, formed on the first thin film encapsulation layer, and connected to the actuation device layer; a second thin film encapsulation layer located in the pixel, formed on the emission layer, coming into contact with the first thin film encapsulation layer, and formed of a second inorganic material; a third thin film encapsulation layer located in the pixel, formed on the second thin film encapsulation layer, and formed of a composite material of organic and inorganic materials; and a stretchable film attached to the flexible substrate to cover the M×N pixels, wherein the stretchable optical device is divided into a high stretchable region having stretchable wrinkles dependent on a shape of the stretchable film, and a low stretchable region for minimizing deformation of the stretchable film, in which the low stretchable region corresponds to a region of the pixels.

According to one embodiment, a product of a modulus and a thickness of the third thin film encapsulation layer may be relatively larger than a product of a modulus and a thickness of the flexible substrate.

According to one embodiment, the product of the modulus and the thickness of the third thin film encapsulation layer may be 100 times or more than the product of the modulus and the thickness of the flexible substrate.

According to one embodiment, an overlapping length between the first thin film encapsulation layer and the second thin film encapsulation layer may be 50 μm or less.

According to one embodiment, the first inorganic material and the second inorganic material may be formed of the same material.

According to one embodiment, the first inorganic material and the second inorganic material may be formed of any one material selected from a group of candidate materials based on inorganic materials including at least one of silicon nitride, silicon oxide and aluminum oxide.

According to one embodiment, the composite material may include a silicone-based organic-inorganic composite hybrid material.

The present invention provides a method for manufacturing a stretchable optical device.

According to one embodiment, the method for manufacturing a stretchable optical device includes the steps of: forming a first thin film encapsulation layer formed of a first inorganic material on a flexible substrate divided into M (a positive integer of 1 or more)×N (a positive integer of 1 or more) pixels; sequentially forming an actuation device layer and an emission layer on the first thin film encapsulation layer for each pixel; forming a second thin film encapsulation layer formed of a second inorganic material on the first thin film encapsulation layer to cover the actuation device layer and the emission layer; forming a third thin film encapsulation layer formed of a composite material of organic and inorganic materials on the second thin film encapsulation layer overlapping with the actuation device layer and the emission layer, on the second thin film encapsulation layer; encapsulating the actuation device layer and the emission layer for each of the pixels by removing the first and second thin film encapsulation layers formed between pixels neighboring to each other; and attaching a pre-stretched stretchable film on the flexible substrate to cover the M×N pixels.

According to one embodiment, the flexible substrate may be first formed on a process substrate, and the process substrate may be removed from the flexible substrate after attaching the stretchable film.

According to one embodiment, the first thin film encapsulation layer and the second thin film encapsulation layer may be formed at a temperature less than or equal to 100° C. through any one of a plasma chemical vapor deposition, an atomic layer deposition, and a physical vapor deposition.

According to one embodiment, the third thin film encapsulation layer may be formed through any one scheme of oxygen (O2) plasma deposition, inkjet, and sputtering.

According to one embodiment, the third thin film encapsulation layer formed through the step of forming the third thin film encapsulation layer may be processed with oxygen (O2) plasma, and the organic material forming the composite material may be volatilized and the inorganic material forming the composite material may be harder when being processed with the oxygen plasma.

According to one embodiment, in the step of encapsulating the actuation device layer and the emission layer, the first thin film encapsulation layer and the second thin film encapsulation layer may be removed by dry etching while using the third thin film encapsulation layer as a shield film.

According to one embodiment, the pixel region may be divided as a low stretchable region in which deformation of the stretchable film is minimized, and a region between the pixels may be divided as a high stretchable region having stretchable wrinkles dependent on a shape of the stretchable film.

According to one embodiment, a product of a modulus and a thickness of the third thin film encapsulation layer may be relatively larger than a product of a modulus and a thickness of the flexible substrate.

### Advantageous Effects

According to the embodiment of the present invention, the stretchable optical device includes: a flexible substrate divided into M (a positive integer of 1 or more)×N (a positive integer of 1 or more) pixels; a first thin film encapsulation layer formed on the flexible substrate, located in the pixel, and formed of a first inorganic material; an actuation device layer located in the pixel and formed on the first thin film encapsulation layer; an emission layer located in the pixel, formed on the first thin film encapsulation layer, and connected to the actuation device layer; a second thin film encapsulation layer located in the pixel, formed on the emission layer, coming into contact with the first thin film encapsulation layer, and formed of a second inorganic material; a third thin film encapsulation layer located in the pixel, formed on the second thin film encapsulation layer, and formed of a composite material of organic and inorganic materials; and a stretchable film attached to the flexible substrate to cover the M×N pixels, wherein the stretchable optical device is divided into a high stretchable region having stretchable wrinkles dependent on a shape of the stretchable film, and a low stretchable region for minimizing deformation of the stretchable film, in which the low stretchable region may correspond to a region of the pixels.

Accordingly, the stretchable optical device and the method for manufacturing the same may be provided, so that excellent external air blocking properties and elongation properties can be implemented.

In addition, according to the embodiment of the present invention, the conventional flexible display substrates can be used, so that excellent mass productivity can be provided.

In addition, according to the embodiment of the present invention, the stretchable optical device can be manufactured at room temperature, so that characteristic changes in the emission layer and the driving layer of an optical device, for example, an organic light emitting device, can be minimized.

In addition, according to the embodiment of the present invention, deformation of the first thin film encapsulation layer formed at a lower portion and deformation of the second thin film encapsulation layer formed at an upper portion, based on the emission layer, can be minimized.

In addition, according to the embodiment of the present invention, the third thin film encapsulation layer formed of an organic insulating film containing a photosensitive material or a siloxane-based organic-inorganic hybrid composite material may be provided, so that an exposure can be performed for each pixel to which an exposure process is applicable, and thus thin film encapsulation can be performed for each pixel.

According to the embodiment of the present invention, the third thin film encapsulation layer can be replaced with an organic thin film encapsulation, thin film encapsulation can be performed for each pixel by using the inkjet application scheme when the photosensitive material is not included, and thin film encapsulation can be performed for each pixel by using the physical vapor deposition scheme using a metal mask when the material is insoluble.

According to the embodiment of the present invention, loss of the third thin film encapsulation layer can be minimized in an environment in which the first thin film encapsulation layer and the second thin film encapsulation layer are dry etched.

### DESCRIPTION OF DRAWINGS

FIG. 1 is a schematic sectional view showing a stretchable optical device according to one embodiment of the present invention.

FIG. 2 is a schematic sectional view showing the stretchable optical device of FIG. 1 in a stretched state.

FIG. 3 is a flowchart showing a method for manufacturing a stretchable optical device according to one embodiment of the present invention.

FIG. 4 is a schematic view for explaining a process in which a process substrate is prepared before step S110 in FIG. 3.

FIG. 5 is a schematic view for explaining step S110 in FIG. 3.

FIG. 6 is a schematic view for explaining step S120 in FIG. 3.

FIG. 7 is a schematic view for explaining step S130 in FIG. 3.

FIGS. 8 to 12 are schematic views for explaining step S140 in FIG. 3.

FIG. 13 is a schematic view for explaining step S150 in FIG. 3.

FIG. 14 is a schematic view for explaining step S160 in FIG. 3.

FIG. 15 is a schematic view for explaining a process in which the process substrate is removed from the stretchable optical device manufactured through the method for manufacturing the stretchable optical device according to one embodiment of the present invention.

FIG. 16 is a schematic view showing the stretchable optical device manufactured through the method for manufacturing the stretchable optical device according to one embodiment of the present invention.

FIG. 17 is a reference view for explaining a stretchable optical device according to Comparative Example 1 of the present invention.

FIG. 18 is a reference view for explaining a stretchable optical device according to Comparative Example 2 of the present invention.

FIG. 19 is a reference view for explaining a stretchable optical device according to Example 1 of the present invention.

FIG. 20 is a graph showing results obtained by measuring water vapor transmission rates (WVTR) of Example 1 and Comparative Examples 1 and 2 of the present invention.

### BEST MODE

### Mode for Invention

Hereinafter, exemplary embodiments of the present invention will be described in detail with reference to the accompanying drawings. However, the technical idea of the present invention is not limited to the exemplary embodiments described herein and may be embodied in other forms. Further, the embodiments are provided to enable contents disclosed herein to be thorough and complete and provided to enable those skilled in the art to fully understand the idea of the present invention.

In the specification herein, when one component is mentioned as being on other component, it signifies that the one component may be placed directly on the other component or a third component may be interposed therebetween. In addition, in drawings, shapes and sizes may be exaggerated to effectively describe the technical content of the present invention.

In addition, although terms such as first, second and third are used to describe various components in various embodiments of the present specification, the components will not be limited by the terms. The above terms are used merely to distinguish one component from another. Accordingly, a first component referred to in one embodiment may be referred to as a second component in another embodiment. Each embodiment described and illustrated herein may also include a complementary embodiment. In addition, the term “and/or” is used herein to include at least one of the components listed before and after the term.

The singular expression herein includes a plural expression unless the context clearly specifies otherwise. In addition, it will be understood that the term such as “include” or “have” herein is intended to designate the presence of feature, number, step, component, or a combination thereof recited in the specification, and does not preclude the possibility of the presence or addition of one or more other features, numbers, steps, components, or combinations thereof. In addition, the term “connection” is used herein to include both indirectly connecting a plurality of components and directly connecting the components.

In addition, in the following description of the embodiments of the present invention, the detailed description of known functions and configurations incorporated herein will be omitted when it possibly makes the subject matter of the present invention unclear unnecessarily.

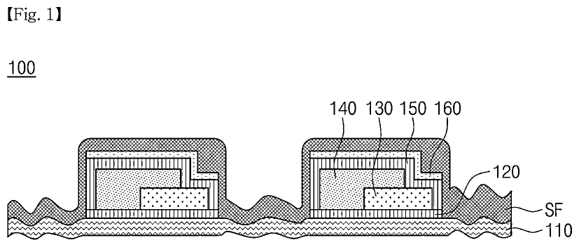

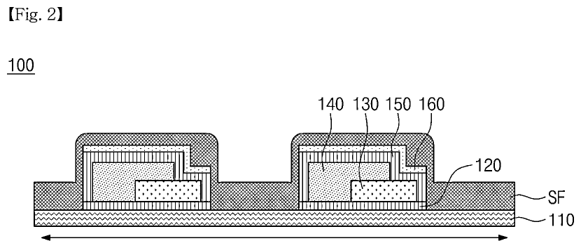

FIG. 1 is a schematic sectional view showing a stretchable optical device according to one embodiment of the present invention. FIG. 2 is a schematic sectional view showing the stretchable optical device of FIG. 1 in a stretched state.

As shown in FIGS. 1 and 2, the stretchable optical device 100 according to one embodiment of the present invention may be a stretchable optical device capable of biaxial elongation.

The stretchable optical device 100 according to one embodiment of the present invention may include a flexible substrate 110, a first thin film encapsulation layer 120, an actuation device layer 130, an emission layer 140, a second thin film encapsulation layer 150, a third thin film encapsulation layer 160, and a stretchable film SF.

The flexible substrate 110 may refer to a substrate having flexibility in the pulling direction as well as flexibility in the bending direction. Accordingly, the flexible substrate 110 may function as a support substrate formed thereon on with the actuation device layer 130 and the emission layer 140 are formed while providing elasticity to the optical device 100.

According to one embodiment of the present invention, the flexible substrate 110 may be divided into M (a positive integer of 1 or more)×N (a positive integer of 1 or more) pixels. Accordingly, the actuation device layer 130 and the emission layer 140 may be formed inside the pixel.

The stretchable optical device 100 according to one embodiment of the present invention may be divided into a high stretchable region and a low stretchable region. The high stretchable region may be defined as a region having stretchable wrinkles dependent on a shape of the stretchable film SF. In addition, the low stretchable region may be defined as a region in which deformation of the stretchable film SF is minimized.

The low stretchable region may be formed due to the large modulus and thickness of the third thin film encapsulation layer 160 formed of a composite material of organic and inorganic materials. Thus, according to one embodiment of the present invention, the pixel region formed therein with the third thin film encapsulation layer 160 may be the low stretchable region.

As described above, when the stretchable optical device 100 according to one embodiment of the present invention is divided into the high stretchable region and the low stretchable region, the flexible substrate 110 forming an exterior of the stretchable optical device 100 may also be divided into a high stretchable region and a low stretchable region.

In the flexible substrate 110, the high stretchable region may be a portion coming into direct contact with the stretchable film SF. The portion of the flexible substrate 110 coming into direct contact with the stretchable film SF may be between neighboring pixels.

In addition, in the flexible substrate 110, the low stretchable region may be a portion coming into indirect contact with the elastic film SF. The portion of the flexible substrate 110 coming into indirect contact with the stretchable film SF may be a pixel region, that is, the pixel region in which the first thin film encapsulation layer 120, the actuation device layer 130, the emission layer 140, the second thin film encapsulation layer 150, and the thin film encapsulation layers 160 are sequentially formed between the flexible substrate 110 and the stretchable film SF.

In other words, in the flexible substrate 110, the low stretchable region may be a region in which the stretchable film SF comes into direct contact with the third thin film encapsulation layer 160 without coming into direct contact with the flexible substrate 110.

According to one embodiment of the present invention, the flexible substrate 110 may be formed of a material used to manufacture the conventional flexible display. For example, the flexible substrate 110 may be formed of at least one material of polyimide, polyethylen terephthalate (PET), polyehylennaphtalate (PEN), and polyehersulfone (PES).

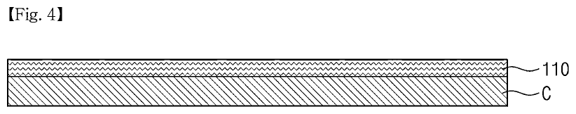

In addition, according to one embodiment of the present invention, the flexible substrate 110 may be supported by a process substrate C (in FIG. 4) during a process of manufacturing the stretchable optical device 100, and may be separated from the process substrate C (in FIG. 4) when the process of manufacturing the optical device 100 is completed. This will be described below in more detail.

The first thin film encapsulation layer 120 may be located inside the pixel. The first thin film encapsulation layer 120 may be formed on the flexible substrate 110.

According to one embodiment of the present invention, the first thin film encapsulation layer 120 may be formed of a first inorganic material. For example, the first thin film encapsulation layer 120 may be formed of any one material selected from a group of candidate materials based on inorganic materials including at least one of silicon nitride, silicon oxide and aluminum oxide.

The actuation device layer 130 may be located inside the pixel. The actuation device layer 130 may be formed on the first thin film encapsulation layer 120. The actuation device layer 130 may include a thin film transistor and a capacitor capable of controlling the emission layer 140 for each pixel.

For example, two transistors and one capacitor may be provided per unit pixel. One of the two transistors may be a switching transistor, and the other may be a driving transistor. However, this is merely exemplary, and the actuation device layer 130 may include more transistors and capacitors.

The transistor may be formed based on various types of semiconductor layers. The semiconductor layer may have a property of providing high mobility. For example, the transistor may include at least one transistor of an oxide transistor utilizing an oxide semiconductor, a low-temperature polysilicon transistor utilizing low-temperature polysilicon as a semiconductor layer, an organic transistor utilizing an organic material as a semiconductor layer, and a single crystal transistor utilizing single crystal silicon as a semiconductor layer.

Although not shown, the transistor may include a metal electrode such as a gate electrode, a source electrode and a drain electrode.

The transistor forming the actuation device layer 130 may be connected to a wiring thin film. The wiring may include, for example, a gate wiring, a data wiring and the like. The gate wiring may be connected to the gate electrode, and the data wiring may be connected to the source electrode.

The wiring may be formed of a material having elasticity and excellent conductivity, for example, an amorphous metal. Particularly, the wiring may be formed of an amorphous metal alloy. The amorphous metal alloy includes any type of alloy composed of two or more metals for mutually interfering with formation of a regular crystal structure, and is not limited to the above-mentioned material examples.

The amorphous metal alloy may be formed of at least one material of, for example, FeZr, CoNi, La—Al—Cu, Al—Sc, ZrTiCuNiBe, AuSi, CuZr, CuPd, CuCo, CuPdCoP, PdAgSi, PdAgSiP, PdAgSiGe, PtCuAgPBSi, PtCuAgPBSi, CuZrTi, CuZrTiNi, and CuZrTiAlBe.

For another example, the wiring may be formed of a material that is bendable with low-resistance. For example, the wiring may be formed of at least one of materials including aluminum, silver, and copper.

The wiring may be formed of a double layer or multi-layer in which a low-resistance material wiring is formed on an amorphous metal alloy wiring.

In addition, the wiring may have a property of maintaining resistance inside 1.5 when being stretched up to 10%.

The emission layer 140 may be located inside the pixel. The emission layer 140 may be formed on the first thin film encapsulation layer 120. In addition, the emission layer 140 may be electrically connected to the actuation device layer 130.

According to one embodiment of the present invention, the emission layer 140 may include at least one layer of a hole injection layer, a hole transfer layer, an emission layer, an electron transfer layer, and an electron injection layer. According to one embodiment of the present invention, the emission layer 140 may also have elasticity. In this case, the emission layer 140 may maintain changes in image quality characteristics to be at 25% or less when being stretched by 10%.

The second thin film encapsulation layer 150 may be located inside the pixel. The second thin film encapsulation layer 150 may be formed on the emission layer 140. According to one embodiment of the present invention, the second thin film encapsulation layer 150 may be formed to surround top and side surfaces of the actuation device layer 130 and the emission layer 140. Accordingly, the second thin film encapsulation layer 150 may come into contact with the first thin film encapsulation layer 120 formed below the actuation device layer 130 and the emission layer 140 to encapsulate the thin films 130 and 140. The second thin film encapsulation layer 150 may come into close contact with the first thin film encapsulation layer 120 so as to prevent a cavity from being formed with the first thin film encapsulation layer 120.

According to one embodiment of the present invention, an overlapping length between the first thin film encapsulation layer 120 and the second thin film encapsulation layer 150 may be 50 μm or less. An overlapping length between the first thin film encapsulation layer 120 and the second thin film encapsulation layer 150 may correspond to a thickness of the second thin film encapsulation layer 150 that forms one side wall surrounding the actuation device layer 130 and the emission layer 140.

Accordingly, when the overlapping length between the first thin film encapsulation layer 120 and the second thin film encapsulation layer 150 is short, it may be advantageous in implementing a high-resolution display.

According to one embodiment of the present invention, the second thin film encapsulation layer 150 may be formed of a second inorganic material. According to one embodiment of the present invention, the second thin film encapsulation layer 150 may be formed of the same material as the first thin film encapsulation layer 120.

In other words, the second inorganic material forming the second thin film encapsulation layer 150 and the first inorganic material forming the first thin film encapsulating layer 120 may be the same material.

Accordingly, like the first thin film encapsulation layer 120, the second thin film encapsulation layer 150 may be formed of any one material selected from a group of candidate materials based on inorganic materials including at least one of silicon nitride, silicon oxide and aluminum oxide.

When the material forming the first thin film encapsulation layer 120 and the material forming the second thin film encapsulation layer 150 are different from each other, a breakage may occur due to differences in adhesion or thermal stress between the two materials.

It may be most exemplary that the second thin film encapsulation layer 150 and the first thin film encapsulation layer 120 are formed of the same material. However, the second thin film encapsulation layer 150 and the first thin film encapsulation layer 120 may be formed of materials having a difference in coefficient of thermal expansion (CTE) less than 10% therebetween. In other words, the second thin film encapsulation layer 150 and the first thin film encapsulation layer 120 may be formed of similar materials even though being the same as each other.

The third thin film encapsulation layer 160 may be located inside the pixel. The third thin film encapsulation layer 160 may be formed on the second thin film encapsulation layer 150. The third thin film encapsulation layer 160 may be formed on the second thin film encapsulation layer 150 to correspond to a top surface of the second thin film encapsulation layer 150.

According to one embodiment of the present invention, a product of a modulus and a thickness of the third thin film encapsulation layer 160 may be relatively larger than a product of a modulus and a thickness of the flexible substrate 110. For example, the product of the modulus and the thickness of the third thin film encapsulation layer 160 may be 100 times or more than the product of the modulus and the thickness of the flexible substrate 110.

For example, When the third thin film encapsulation layer 160 has a modulus of 30 GPa and a thickness of 1 μm, and the flexible substrate 110 has a modulus of 1 GPa and a thickness of 300 nm, the product of the modulus and the thickness of the third thin film encapsulation layer 160 may be 100 times the product of the modulus and the thickness of the flexible substrate 110.

The product of modulus and thickness by 100 times or more may signify that a difference in deformation by 100 times or more may occur under the same stress.

Accordingly, the third thin film encapsulation layer 160 having the larger product of modulus and thickness may not shrink even though the pre-stretched stretchable film SF shrinks, and accordingly, a portion of the stretchable film SF attached to the third thin film encapsulation layer 160 may be eventually prevented from shrinking. Thus, according to one embodiment of the present invention, a pixel region formed therein with the third thin film encapsulation layer 160 may be divided as a low stretchable region.

Whereas, the region of the flexible substrate 110 having the relatively smaller product of modulus and thickness and coming into direct contact with the pre-stretched stretch film SF may shrink dependent on a shrinking shape of the stretchable film SF when the pre-stretched stretch film SF shrinks. Accordingly, stretchable wrinkles may be generated in the region of the flexible substrate 110 coming into direct contact with the pre-stretched stretchable film SF, and may be divided as a high stretchable region distinct from the low stretchable region defined as the pixel region and having no stretchable wrinkles.

In addition, according to one embodiment of the present invention, the third thin film encapsulation layer 160 may formed of a composite material of organic and inorganic materials. The composite material of organic and inorganic materials for forming the third thin film encapsulation layer 160 may include a silicone-based organic-inorganic composite hybrid material.

For example, the third thin film encapsulation layer 160 may be formed of a silicon-based organic-inorganic composite hybrid material, such as organic trialkoxysilane (RSi(OR′)3), organic dialkoxysilane (RSiMe(OR′)2) and bistrialkoxyryl ((R′O)3SiC3H6-X—C3H6Si(OR′)3).

The stretchable film SF may be attached onto the flexible substrate 110 to cover the M×N pixels The stretchable film SF may be attached to the flexible substrate 110 in a pre-stretched state.

When a force stretching the stretchable film SF is removed, the stretchable film SF may naturally shrink in the opposite direction of stretching. Accordingly, the highly stretchable region coming into direct contact with the stretch film SF may also shrink, so as to have stretchable wrinkles dependent on the shrinking shape of the stretchable film SF.

Whereas, the low stretchable region, that is, the portion formed therein with the third thin film encapsulation layer 160 may not shrink due to the high modulus and thickness of the third thin film encapsulation layer 160. In other words, a part of the stretchable film SF attached to the low stretchable region may have minimized deformation even when the stretching force is removed.

According to one embodiment of the present invention, stretchable 3M tape, polyurethane (PU), styrene ethylene butylene styrene (SEBS), polydimethylsiloxane (PDMS) or the like may be used as the stretchable film SF.

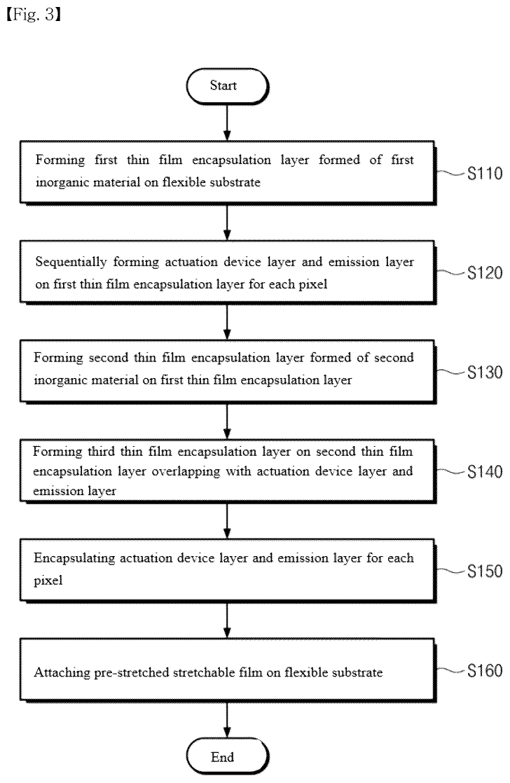

Hereinafter, the method for manufacturing the stretchable optical device according to one embodiment of the present invention will be described with reference to FIGS. 3 to 16.

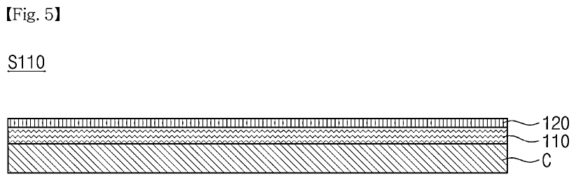

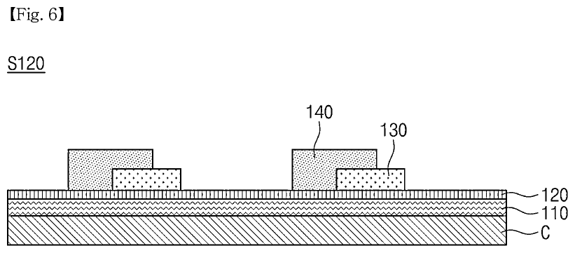

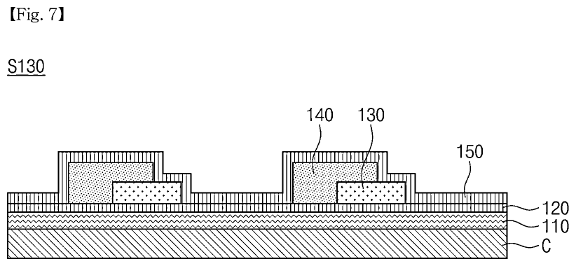

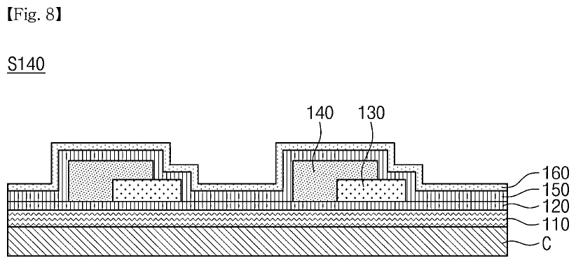

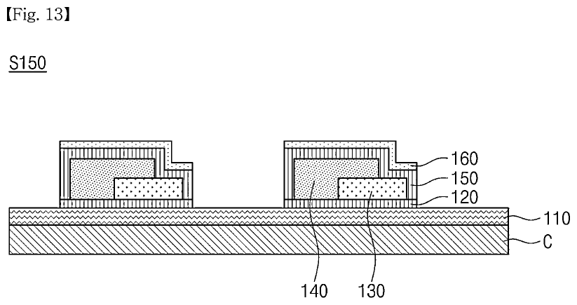

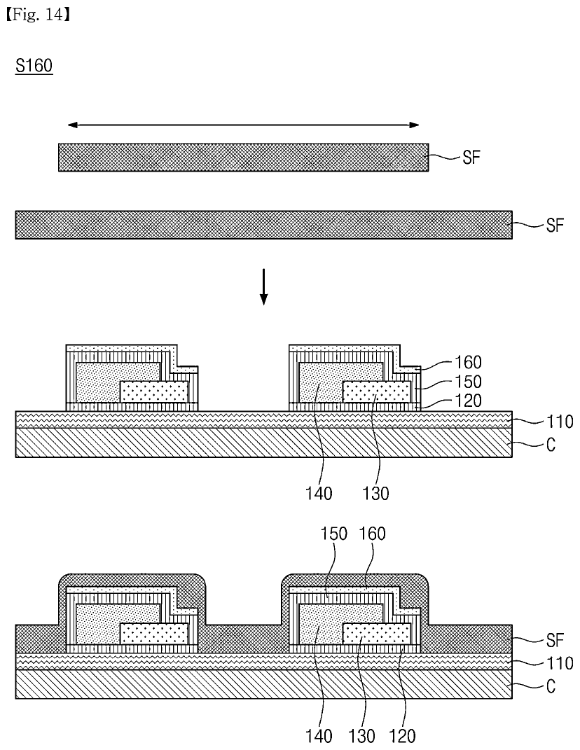

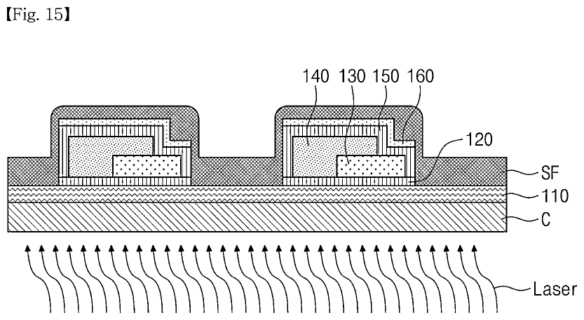

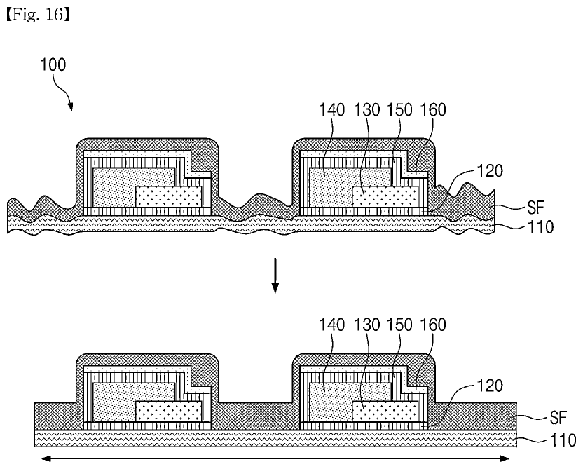

FIG. 3 is a flowchart showing a method for manufacturing a stretchable optical device according to one embodiment of the present invention. FIG. 4 is a schematic view for explaining a process in which a process substrate is prepared before step S110 in FIG. 3. FIG. 5 is a schematic view for explaining step S110 in FIG. 3. FIG. 6 is a schematic view for explaining step S120 in FIG. 3. FIG. 7 is a schematic view for explaining step S130 in FIG. 3. FIGS. 8 to 12 are schematic views for explaining step S140 in FIG. 3. FIG. 13 is a schematic view for explaining step S150 in FIG. 3. FIG. 14 is a schematic view for explaining step S160 in FIG. 3. FIG. 15 is a schematic view for explaining a process in which the process substrate is removed from the stretchable optical device manufactured through the method for manufacturing the stretchable optical device according to one embodiment of the present invention. FIG. 16 is a schematic view showing the stretchable optical device manufactured through the method for manufacturing the stretchable optical device according to one embodiment of the present invention.

Referring to FIG. 3, the method for manufacturing a stretchable optical device according to one embodiment of the present invention includes the steps of: forming a first thin film encapsulation layer formed of a first inorganic material on a flexible substrate (S110); sequentially forming an actuation device layer and an emission layer on the first thin film encapsulation layer for each pixel (S120); forming a second thin film encapsulation layer formed of a second inorganic material on the first thin film encapsulation layer (S130); forming a third thin film encapsulation layer on the second thin film encapsulation layer overlapping with the actuation device layer and the emission layer (S140); encapsulating the actuation device layer and the emission layer for each pixel (S150); and attaching a pre-stretched stretchable film on the flexible substrate (S160).

Step S110

Referring to FIG. 5, first, in step S110, a first thin film encapsulation layer 120 formed of a first inorganic material may be formed on a flexible substrate 110 divided into M (a positive integer of 1 or more)×N (a positive integer of 1 or more) pixels.

Referring to FIG. 4, a process substrate C may be attached to a bottom surface of the flexible substrate 110 before forming the first thin film encapsulation layer 120 on the flexible substrate 110.

A glass substrate containing a sacrificial layer (not shown) may be used as the process substrate C so as to be separated from the flexible substrate 110 upon completion of manufacturing the stretchable optical device 100 (in FIG. 16).

For example, amorphous silicon containing hydrogen (a-Si:H), and amorphous silicon nitride containing hydrogen (a-SiNx:H) may be used a material used as the sacrificial layer (not shown).

The sacrificial layer (not shown) may generate hydrogen gas when a laser is irradiated, so that the process substrate C and the flexible substrate 120 may be separated from each other.

In addition, in step S110, materials used in the conventional flexible display manufacturing processes may be used for the flexible substrate 120. For example, in step S110, at least one material of polyimide, polyethylen terephthalate (PET), polyehylennaphtalate (PEN), and polyehersulfone (PES) may be used as the flexible substrate 120.

In step S110, a first thin film encapsulation layer 120 formed of a first inorganic material may be formed on the flexible substrate 110 supported by the process substrate C. In step S110, the first thin film encapsulation layer 120 may be formed by using inorganic materials used in the conventional thin film encapsulation processes.

For example, in step S110, the first thin film encapsulation layer 120 may be formed by using any one material selected from a group of candidate materials based on inorganic materials including at least one of silicon nitride, silicon oxide and aluminum oxide.

According to one embodiment of the present invention, in step S110, the first thin film encapsulation layer 120 may be formed at a low temperature. For example, in step S110, the first thin film encapsulation layer 120 may be formed at a maximum temperature of 100° C. or lower through any one deposition of a plasma chemical vapor deposition, an atomic layer deposition, and a physical vapor deposition.

Thus, according to one embodiment of the present invention, the first thin film encapsulation layer 120 may be formed of an inorganic material, and may not be allowed to contain an organic material such as polymer. When the organic material is contained in the first thin film encapsulation layer 120, long-term reliability cannot be provided to light emitting devices forming a display.

Step S120

Referring to FIG. 6, in step S120, an actuation device layer 130 and an emission layer 140 may be sequentially formed for each pixel on the first thin film encapsulation layer 120.

First, in step S120, the actuation device layer 130 may be formed on the first thin film encapsulation layer 120. The actuation device layer 130 may include a thin film transistor and a capacitor capable of controlling the emission layer 140 for each pixel.

For example, two transistors (a switching transistor and a driving transistor) and one capacitor may be provided per unit pixel. However, this is merely exemplary, and more transistors and capacitors may be provided. A structure without the transistor and the capacitor may also be included in the method for manufacturing the stretchable optical device according to the present invention.

The transistor may be formed based on various semiconductor layers. The semiconductor layer may have a property of providing high mobility. For example, the transistor may include at least one transistor of an oxide transistor utilizing an oxide semiconductor, a low-temperature polysilicon transistor utilizing low-temperature polysilicon as a semiconductor layer, an organic transistor utilizing an organic material as a semiconductor layer, and a single crystal transistor utilizing single crystal silicon as a semiconductor layer.

The transistor may include a metal electrode such as a gate electrode, a source electrode and a drain electrode.

The actuation device layer 130 including the above transistors and capacitors may be connected by a wiring thin film. The wiring may include, for example, a plurality of gate wirings and data wirings formed in directions crossing each other on the flexible substrate 110 to define the pixel. The gate wiring may be connected to a gate electrode of the transistor, and the data wiring may be connected to a source electrode of the transistor.

The wiring may be formed of a material having elasticity and excellent conductivity. For example, the wiring may be formed of an amorphous metal, particularly an amorphous metal alloy. The amorphous metal alloy includes any type of alloy composed of two or more metals for mutually interfering with formation of a regular crystal structure, and is not limited to the above-mentioned material examples.

The amorphous metal alloy may be formed of, for example, at least one of FeZr, CoNi, La—Al—Cu, Al—Sc, ZrTiCuNiBe, AuSi, CuZr, CuPd, CuCo, CuPdCoP, PdAgSi, PdAgSiP, PdAgSiGe, PtCuAgPBSi, PtCuAgPBSi, CuZrTi, CuZrTiNi, and CuZrTiAlBe.

For another example, the wiring may be formed of a material that is bendable with low-resistance. For example, the wiring may be formed of at least one of aluminum, copper and silver.

The wiring may be formed of a double layer or multi-layer in which a low-resistance material wiring is formed on an amorphous metal alloy wiring. In addition, the wiring may have a property of maintaining resistance inside 1.5 when being stretched up to 10%.

Next, in step S120, the emission layer 140 may be formed on the first thin film encapsulation layer 120. The emission layer 140 may include at least one layer of a hole injection layer HIL, a hole transport layer HTL, an emission layer EL, an electron transport layer ETL, and an electron injection layer EIL.

According to one embodiment of the present invention, the emission layer 140 may also have elasticity. In this case, the emission layer 140 may maintain change in image quality characteristics to be at 25% or less when being stretched by 10%.

Before forming the emission layer 140, a first electrode electrically connected to the drain electrode of the transistor of the actuation device layer 130 may be formed. The first electrode may function as a positive electrode or a negative electrode for the emission layer 140.

In this case, the emission layer 140 may be configured such that the hole injection layer, the hole transport layer, the emission layer, the electron transport layer, and the electron injection layer are sequentially laminated when the first electrode is a positive electrode. When the first electrode is the negative electrode, the above layers may be laminated in a reversed order.

The first electrode may be provided per pixel, and an organic bank for separating pixels may be formed on the first electrode.

In step S120, the emission layer 140 may be formed in various ways. For example, in step S120, the emission layer 140 may be formed through a vapor deposition scheme using a shadow mask.

Step S130

Referring to FIG. 7, in step S130, a second thin film encapsulation layer 150 may be formed on the first thin film encapsulation layer 120. In step S130, the second thin film encapsulation layer 150 may be formed to cover the actuation device layer 130 and the emission layer 140.

In step S130, the second thin film encapsulation layer 150 may be formed by using an inorganic material. In step S130, the second thin film encapsulation layer 150 may be formed by using the inorganic material used to form the first thin film encapsulation layer 120. This is because, when the first thin film encapsulation layer 120 and the second thin film encapsulation layer 150 are formed of materials different from each other, a breakage may occur due to differences in adhesion or thermal stress between two materials.

In step S130, the second thin film encapsulation layer 150 may be formed by using, for example, any one material selected from a group of candidate materials based on inorganic materials including at least one of silicon nitride, silicon oxide and aluminum oxide.

According to one embodiment of the present invention, in step S130 like the first thin film encapsulation layer 120, the second thin film encapsulation layer 150 may also be formed at a low temperature. Accordingly, the properties of the actuation device layer 130 and the emission layer 140 may be prevented from being deteriorated. The properties of the actuation device layer 130 and the emission layer 140 may be deteriorate during a high temperature process.

For example, in step S130, the second thin film encapsulation layer 150 may be formed at 100° C. or less through any one deposition of a plasma chemical vapor deposition, an atomic layer deposition, and a physical vapor deposition.

Thus, according to one embodiment of the present invention, like the first thin film encapsulation layer 120, the second thin film encapsulation layer 150 may be formed of an inorganic material, and cannot contain an organic material such as polymer. In addition, according to one embodiment of the present invention, an organic material or an empty space may not be formed between the first thin film encapsulation layer 120 and the second thin film encapsulation layer 150.

When the organic material or the empty space is formed between the first thin film encapsulation layer 120 and the second thin film encapsulation layer 150, external air may be permeated therethrough and cracks may occur very easily in inorganic materials on the organic material.

Step S140

Referring to FIGS. 8 to 10, in step S140, a third thin film encapsulation layer 160 having a high Young's modulus may be formed on the second thin film encapsulation layer 150. In step S140, the third thin film encapsulation layer 160 may be formed on the second thin film encapsulation layer 150 overlapping with the actuation device layer 130 and the emission layer 140. In other words, in step S140, the third thin film encapsulation layer 160 may be formed inside the pixel.

Referring to FIG. 8, first, in step S140, the third thin film encapsulation layer 160 may be formed on the second thin film encapsulation layer 150.

In step S140, the third thin film encapsulation layer 160 may be formed by using a composite material of organic and inorganic materials. For example, in step S140, the third thin film encapsulation layer 160 may be formed by using a silicone-based organic-inorganic composite hybrid material, such as organic trialkoxysilane (RSi(OR′)3), organic dialkoxysilane (RSiMe(OR′)2) and bistrialkoxyryl ((R′O)3SiC3H6-X—C3H6Si(OR′)3), used in the conventional flexible display manufacturing process.

The composite material forming the third thin film encapsulation layer 160 may contain a photosensitive agent capable of exposure and development processes. The photosensitive agent may include photo sensitizer, photo initiator, monomer, binder polymer, and solvent.

In addition, the composite material forming the third thin film encapsulation layer 160 may undergo solvent volatilization and sufficient curing at a temperature of 100° C. or less. A vacuum environment and an ultraviolet ray environment may be used to cure the conventional organic-inorganic composite materials, which are allowed to be cured at 100° C. or higher, at a low temperature.

In order to prevent the properties of the emission layer 140 from being deteriorated under the ultraviolet ray environment, an ultraviolet absorbing layer (not shown) may be included between the emission layer 140 and the second thin film encapsulation layer 150, and the second thin film encapsulation layer 150 itself may absorb ultraviolet rays.

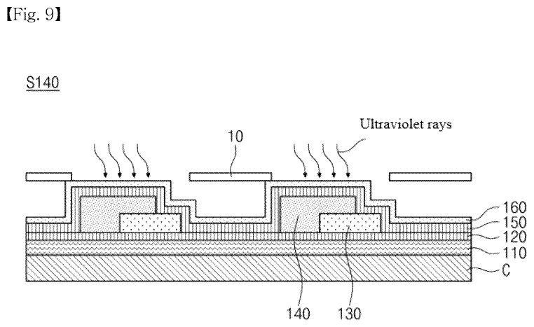

Next, referring to FIG. 9, in step S140, the third thin film encapsulation layer 160 other than the pixels may be covered by a photo mask 10 containing a chrome metal. Thereafter, in step S140, ultraviolet rays may be irradiated in order to cure a region of the third thin film encapsulation layer 160 exposed above the photo mask 10.

The irradiated ultraviolet rays may include g-line (436 nm), h-line (405 nm), i-line (365 nm), KrF deep UV (248 nm), ArF deep UV (193 nm), vacuum UV (157 nm), and EUV (13.5 nm).

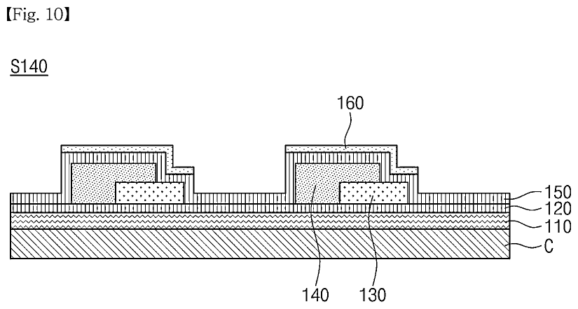

Referring to FIG. 10, the region of the third thin film encapsulation layer 160 covered by the photo mask 10 may be dissolved by developer. The developer may contain an organic solvent such as 3-pentanone and propylen glycol monomethyl ether actate.

The developer may not include a highly acidic or highly basic material that causes unintended corrosion in the region of the third thin film encapsulation layer 160 exposed above the photo mask 10.

Accordingly, in step S140, the third thin film encapsulation layer 160 may be formed in a pixel unit.

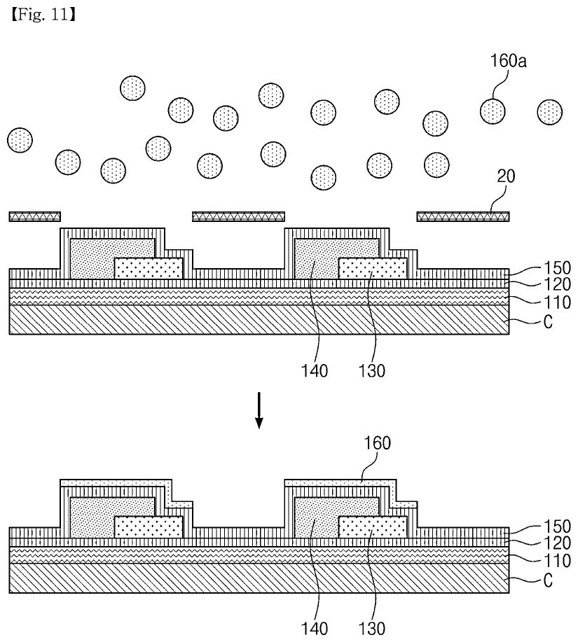

In addition, as shown in FIG. 11, according to another embodiment, a region other than the region to be formed therein with the third thin film encapsulation layer 160 may be covered using a metal mask 20 and then a composite material 160a of organic and inorganic materials, which is configured to form the third thin film encapsulation layer 160, may be deposited through a physical vapor deposition scheme, so that the third thin film encapsulation layer 160 may be formed. In other words, according to another embodiment, the third thin film encapsulation layer 160 may be formed in a pixel unit by using the metal mask 20.

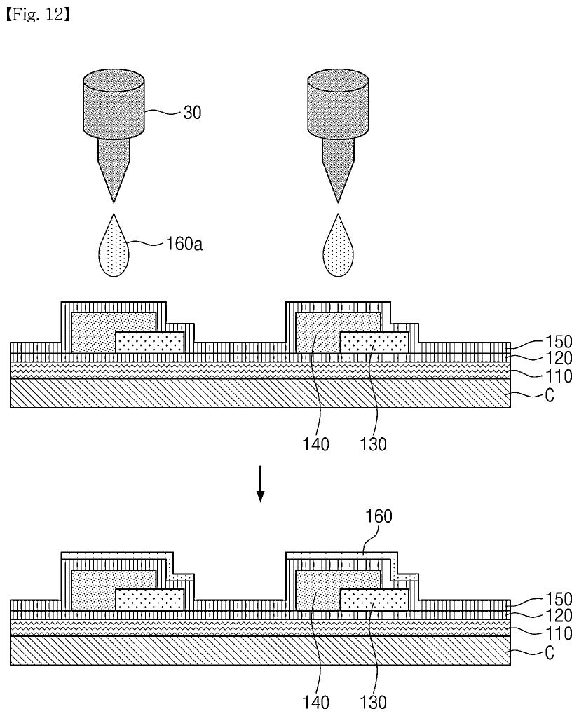

In addition, as shown in FIG. 12, according to another embodiment, the composite material 160a of organic and inorganic materials, which is configured to form the third thin film encapsulation layer 160, may be applied to a desired region through an inkjet nozzle 30, so that the third thin film encapsulation layer 160 may be formed in a pixel unit.

In addition, in step S140, the third thin film encapsulation layer 160 may be formed on the second thin film encapsulation layer 150 and then the third thin film encapsulation layer 160 may be processed with oxygen plasma, as a post-processing process. When the oxygen plasma environment is created, organic materials may be volatilized from the composite materials forming the third thin film encapsulation layer 160 and only a layer composed of inorganic materials may remain. In this case, the layer composed of the inorganic materials may become harder.

Step S150

Referring to FIG. 13, in step S150, the first thin film encapsulation layer 120 and the second thin film encapsulation layer 150 formed between neighboring pixels may be removed, so that the actuation device layer 130 and the emission layer 140 may be encapsulated for each pixel.

In step S150, the third thin film encapsulation layer 160 may be used as a shield film, so that the first thin film encapsulation layer 120 and the second thin film encapsulation layer 150 may be removed through dry etching.

The first thin film encapsulation layer 120 and the second thin film encapsulation layer 150 may be removed with little loss of the third thin film encapsulation layer 160 in a fluorine and oxygen plasma environment.

During the dry etching process for the first thin film encapsulation layer 120 and the second thin film encapsulation layer 150, the inorganic layer forming the third thin film encapsulation layer 160 may become harder, so that a subsequent process, such as a color filter formation process, may be possible without an additional inorganic layer.

For example, when removing rates of the first and second thin film encapsulation layers 120 and 150 having a thickness of 200 nm and the third thin film encapsulation layer 160 having a thickness of 1 μm are the same, at least 80% of the thickness of the third thin film encapsulation layer 160 may remain even after the dry etching is completed.

Through step S150, lower portions of the actuation device layer 130 and the emission layer 140 may be surrounded by the first thin film encapsulation layer 120, and sides portion and top portions of the actuation device layer 130 and the emission layer 140 may be surrounded by the second thin film encapsulation layer 150.

In other words, the actuation device layer 130 and the emission layer 140 may be encapsulated in a pixel unit by the first thin film encapsulation layer 120 and the second thin film encapsulation layer 150.

Step S160

Referring to FIG. 14, in step S160, a pre-stretched stretchable film SF may be attached onto the flexible substrate 110 to cover the M×N pixels. Before being attached to the flexible substrate 110, the pre-stretched stretchable film SF may be fixed by a structure.

For example, the pre-stretched stretchable film SF may be fixed outside using magnets, screws, or structures having rough surfaces.

In step S160, a glue or an adhesive may be used for adhesion between the stretchable film SF and the flexible substrate 110. In step S160, a glue or an adhesive, which may have adhesion at a low temperature, may be used.

In addition, in step S160, a glue or an adhesive, which may has stronger adhesive strength in ultraviolet ray environment, may be used. In addition, in step S160a glue or an adhesive, which may have stronger adhesive strength as time passes, may be used.

In addition, as shown in FIG. 15, in the method for manufacturing the stretchable optical device according to one embodiment of the present invention, the process substrate C may be separated from the flexible substrate 110 after step S160.

For example, in the method for manufacturing the stretchable optical device, the process substrate C may be removed from the flexible substrate 110 by irradiating a laser in the form of a line beam. In the method for manufacturing the stretchable optical device, the laser may be irradiated while targeting the sacrificial layer (not shown) on the process substrate C. When the sacrificial layer (not shown) is removed by the laser irradiation, the separation between the process substrate C and the flexible substrate 110 may be performed.

As shown in FIG. 16, when the process substrate C is removed from the flexible substrate 110, the stretchable optical device 100 according to one embodiment of the present invention may be manufactured.

The stretchable optical device 100 manufactured through the method for manufacturing the stretchable optical device according to one embodiment of the present invention may be divided into a high stretchable region and a low stretchable region. The high stretchable region may be defined as a region having stretchable wrinkles dependent on a shape of the stretchable film SF. In addition, the low stretchable region may be defined as a region in which deformation of the stretchable film SF is minimized.

When the process substrate C is removed, the pre-stretched stretchable film SF may shrink in the direction opposite to stretching. The region of the flexible substrate 110 divided as the high stretchable region and directly bonded to the stretchable film SF may have stretchable wrinkles dependent on a shape of the shrinking stretchable film SF.

In contrast, the pixel region divided as the low stretchable region and including the third thin film encapsulation layer 160 directly bonded to the stretchable film SF may not shrink due to the high modulus and thickness of the third thin film encapsulation layer 160, even though the pre-stretched stretchable film SF shrinks in the direction opposite to the stretching.

Accordingly, the stretchable optical device 100 is divided into the high stretchable region and the low stretchable region, due to the difference between the product of the modulus and thickness of the third thin film encapsulation layer 160 and the product of the modulus and thickness of the flexible substrate 110.

For example, the product of the modulus and thickness of the third thin film encapsulation layer 160 may be larger than the product of the modulus and thickness of the flexible substrate 110. Accordingly, the difference in the product of the modulus and thickness by 100 times or more may cause a difference in deformation by 100 times or more under the same stress.

For example, since a difference in the product of modulus and thickness between the third thin film encapsulation layer 160 having a modulus of 30 GPa and a thickness of 1 μm and the flexible substrate 110 having a modulus of 1 GPa and a thickness of 300 nm is 100 times, the third thin film encapsulation layer 160 and the flexible substrate 110 may cause a difference in deformation by 100 times under the same stress. In other words, when the third thin film encapsulation layer 160 does not shrink, the flexible substrate 110 may shrink.

The embodiments of the present invention have been described and limited to the display. However, the stretchable optical device 100 according to one embodiment of the present invention may be applied to various material device fields such as top-emitting stretchable displays, bottom-emitting stretchable displays, top-absorbing solar cells, and bottom-absorbing solar cells.

The conventional flexible display process may correspond up to the processes of forming the above-described process substrate C, flexible substrate 110, actuation device layer 130, emission layer 140, first thin film encapsulation layer 120, and second thin film encapsulation layer 150. Accordingly, the conventional mass production processes may also be used in the stretchable display manufacturing process, so that excellent mass production compatibility can be provided.

In addition, the fields to which the stretchable optical device manufacturing method according to one embodiment of the present invention is applicable are not limited, so that limitations on the expansion of stretchable form factors into a wide range of fields can be resolved.

According to one embodiment of the present invention, the stretchable film SF may be attached, in which the high stretchable region is the region attached with the material (flexible substrate) and the stretchable film SF having the smaller product of modulus and thickness, and the low stretchable region is the region attached with the material (third thin film encapsulation layer) and the stretchable film SF having the larger product of modulus and thickness.

Accordingly, the region formed therein with the third thin film encapsulation layer 160 having the larger product of modulus and thickness is free from mechanical stress, so that the emission layer 140 and the actuation device layer 130 can have properties to be implemented in the conventional rigid or flexible displays.

In addition, according to one embodiment of the present invention, etching non-uniformity caused by the large-area process can be resolved under an environment in which the dry etching selection ratio of the third thin film encapsulation layer 160 and the first and second thin film encapsulation layers 120 and 150 is secured.

Thus, in the stretchable optical device 100 manufactured through the method for manufacturing the stretchable optical device according to one embodiment of the present invention, deterioration in properties due to external air can be prevented from being generated despite stretching directions, and reliability of 90% or more can be secured based on reliability of organic light emitting diodes encapsulated in glass or metal cans.

### Comparison Example 1

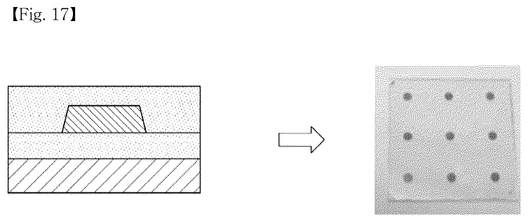

Referring to FIG. 17, in Comparative Example 1, a calcium metal, which is easily oxidized, is encapsulated by using an inorganic-based first thin film encapsulation layer and an inorganic-based second thin film encapsulation layer, in order to test water vapor transmission properties. In Comparative Example 1, the first thin film encapsulation layer is formed on the entire top surface of the substrate instead of encapsulating the calcium metal for each of a plurality of divided pixels on the substrate, the calcium metal is formed thereon and then the second thin film encapsulation layer is formed on the first thin film encapsulation layer to cover the calcium metal.

### Comparison Example 2

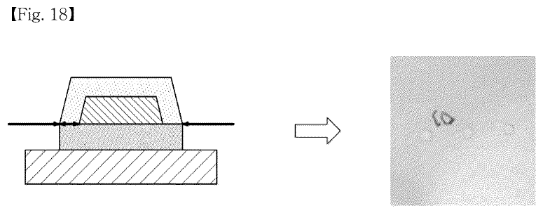

Referring to FIG. 18, in Comparative Example 2, a calcium metal is encapsulated by using an inorganic-based first thin film encapsulation layer and an inorganic-based second thin film encapsulation layer, in order to test water vapor transmission properties. In Comparative Example 2, the calcium metal is encapsulated for each of a plurality of divided pixels on the substrate, and particularly, the second thin film encapsulation layer is formed by using a material different from a material formed as the first thin film encapsulation layer.

For example, in Comparative Example 2, the second thin film encapsulation layer is formed by using a material having a coefficient of thermal expansion (CTE) difference of 10% or more compared to the material formed as the first thin film encapsulation layer.

### Example 1

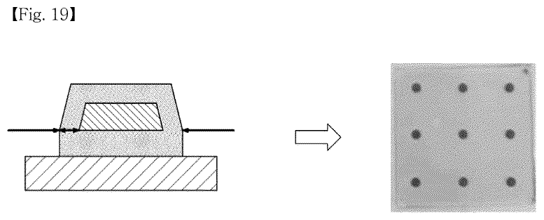

Referring to FIG. 19, in Example 1, a calcium metal is encapsulated by using an inorganic-based first thin film encapsulation layer and an inorganic-based second thin film encapsulation layer, in order to test water vapor transmission properties. In Example 1, the calcium metal is encapsulated for each of a plurality of divided pixels on the substrate, and particularly, the second thin film encapsulation layer is formed by using a material the same as or similar to the material formed as the first thin film encapsulation layer.

For example, in Example 1, the second thin film encapsulation layer is formed by using a material having a coefficient of thermal expansion (CTE) difference of less than 10% compared to the material formed as the first thin film encapsulation layer.

First, based on comparison between Comparative Example 1 and Comparative Example 2, it is confirmed that discoloration of the calcium metal in Comparative Example 2 is more severe. It is confirmed that the encapsulation property is excellent when a lateral moisture penetration path is longer.

In addition, based on comparison between Comparative Example 2 and Example 1, it is confirmed that discoloration of the calcium metal is severe in the case in which the lateral moisture penetration paths are the same, and in the case of Comparative Example 2 in which the first thin film encapsulation layer and the second thin film encapsulation layer are formed of different materials. It is confirmed that discoloration of the calcium metal is minimized in the case of Example 1 in which the first thin film encapsulation layer and the second thin film encapsulation layer are formed of the same or similar material.

Based on comparison between Comparative Example 1 and Example 1, it is confirmed that better encapsulation properties are exhibited when the first thin film encapsulation layer and the second thin film encapsulation layer are formed of the same or similar material compared to when the lateral moisture penetration path is longer.

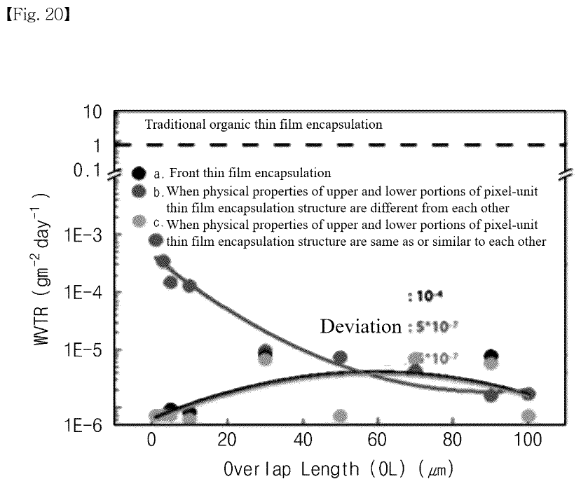

FIG. 20 is a graph showing results obtained by measuring water vapor transmission rates (WVTR) of Example 1 and Comparative Examples 1 and 2 of the present invention.

Referring to FIG. 20, it is confirmed that all of Comparison Example 1 (a. front thin film encapsulation), Comparison Example 2 (b. when physical properties of upper and lower portions of pixel-unit thin film encapsulation structure are different from each other), and Example 1 (c. when physical properties of upper and lower portions of pixel-unit thin film encapsulation structure are same as or similar to each other) have water vapor transmission rate (WVTR) values significantly lower than that of the traditional organic thin film encapsulation.

In Example 1, it is confirmed that a low water vapor transmission rate (WVTR) property is exhibited even in a section having a short overlap length OL in which the first thin film encapsulation layer and the second thin film encapsulation layer for encapsulating the calcium metal overlap with each other.

In other words, in Example 1, it is measured to have a water vapor transmission rate (WVTR) up to 10⁻⁶ g/m² day in a pixel unit thin film encapsulation structure having an overlap length OL of 1 μm in which the first thin film encapsulation layer and the second thin film encapsulation layer overlap with each other.

In addition, in Comparative Example 2, a high water vapor transmission rate (WVTR) is exhibited in a section with an overlap length OL in which the first thin film encapsulation layer and the second thin film encapsulation layer for encapsulating the calcium metal overlap with each other. In other words, it is confirmed that the encapsulation properties are not good, and the water vapor transmission rate (WVTR) is gradually decreased as the overlap length OL between the first thin film encapsulation layer and the second thin film encapsulation layer is increased.

Although the present invention has been described in detail by using exemplary embodiments, the scope of the present invention is not limited to the specific embodiments, and will be interpreted by the appended claims. In addition, it will be apparent that a person having ordinary skill in the art may carry out various deformations and modifications for the embodiments described as above inside the scope without departing from the present invention.

### DESCRIPTION OF REFERENCE NUMERALS

100: Stretchable optical device 110: Flexible substrate
120: First thin film encapsulation layer
130: actuation device 140: Emission layer
150: Second thin film encapsulation layer
160: Third thin film encapsulation layer
160a: Composite material 10: Photo mask
20: Metal mask 30: Inkjet nozzle
C: Process substrate SF: Stretchable film

1. A stretchable optical device comprising:
a flexible substrate divided into M (a positive integer of 1 or more)×N (a positive integer of 1 or more) pixels;
a first thin film encapsulation layer formed on the flexible substrate, located in the pixel, and formed of a first inorganic material;
an actuation device layer located in the pixel and formed on the first thin film encapsulation layer;
an emission layer located in the pixel, formed on the first thin film encapsulation layer, and connected to the actuation device layer;
a second thin film encapsulation layer located in the pixel, formed on the emission layer, coming into contact with the first thin film encapsulation layer, and formed of a second inorganic material;
a third thin film encapsulation layer located in the pixel, formed on the second thin film encapsulation layer, and formed of a composite material of organic and inorganic materials; and
a stretchable film attached to the flexible substrate to cover the M×N pixels, wherein
the stretchable optical device is divided into a high stretchable region having stretchable wrinkles dependent on a shape of the stretchable film, and a low stretchable region for minimizing deformation of the stretchable film, in which the low stretchable region includes a region of the pixels.

2. The stretchable optical device of claim 1, wherein a product of a modulus and a thickness of the third thin film encapsulation layer is relatively larger than a product of a modulus and a thickness of the flexible substrate.

3. The stretchable optical device of claim 2, wherein the product of the modulus and the thickness of the third thin film encapsulation layer is 100 times or more than the product of the modulus and the thickness of the flexible substrate.

4. The stretchable optical device of claim 1, wherein an overlapping length between the first thin film encapsulation layer and the second thin film encapsulation layer is 50 μm or less.

5. The stretchable optical device of claim 1, wherein the first inorganic material and the second inorganic material are formed of a same material.

6. The stretchable optical device of claim 5, wherein the first inorganic material and the second inorganic material are formed of any one material selected from a group of candidate materials based on inorganic materials including at least one of silicon nitride, silicon oxide and aluminum oxide.

7. The stretchable optical device of claim 1, wherein the composite material includes a silicon-based organic-inorganic composite hybrid material.

8. A method for manufacturing a stretchable optical device, the method comprising:
forming a first thin film encapsulation layer formed of a first inorganic material on a flexible substrate divided into M (a positive integer of 1 or more)×N (a positive integer of 1 or more) pixels;
sequentially forming an actuation device layer and an emission layer on the first thin film encapsulation layer for each pixel;
forming a second thin film encapsulation layer formed of a second inorganic material on the first thin film encapsulation layer to cover the actuation device layer and the emission layer;
forming a third thin film encapsulation layer formed of a composite material of organic and inorganic materials on the second thin film encapsulation layer overlapping with the actuation device layer and the emission layer, on the second thin film encapsulation layer;
encapsulating the actuation device layer and the emission layer for each of the pixels by removing the first and second thin film encapsulation layers formed between pixels neighboring to each other; and
attaching a pre-stretched stretchable film on the flexible substrate to cover the M×N pixels.

9. The method of claim 8, wherein the flexible substrate is first formed on a process substrate, and the process substrate is removed from the flexible substrate after the attaching of the stretchable film.

10. The method of claim 8, wherein
the first thin film encapsulation layer and the second thin film encapsulation layer
are formed at a temperature less than or equal to 100° C. through any one deposition of a plasma chemical vapor deposition, an atomic layer deposition, and a physical vapor deposition.

11. The method of claim 8, wherein the third thin film encapsulation layer is formed through any one of oxygen (O2) plasma deposition, inkjet, and sputtering.

12. The method of claim 8, wherein the third thin film encapsulation layer formed through the forming of the third thin film encapsulation layer is processed with oxygen (O2) plasma, in which
the organic material forming the composite material is volatilized and the inorganic material forming the composite material is harder when being processed with the oxygen plasma.

13. The method of claim 8, wherein
the encapsulating of the actuation device layer and the emission layer includes
removing the first thin film encapsulation layer and the second thin film encapsulation layer by dry etching while using the third thin film encapsulation layer as a shield film.

14. The method of claim 8, wherein a region of the pixels is divided as a low stretchable region in which deformation of the stretchable film is minimized, and a region between the pixels is divided as a high stretchable region having stretchable wrinkles dependent on a shape of the stretchable film.

15. The method of claim 8, wherein the third thin film encapsulation layer has a product of a modulus and a thickness relatively larger than a product of a modulus and a thickness of the flexible substrate.
